(19) United States
(12) Patent Application Publication
(10) Pub. No.: US 2026/0343852 A1
(43) Pub. Date: Oct. 29, 2026

(54) SEMICONDUCTOR DEVICE AND MANUFACTURING METHOD THEREFOR

(71) Applicant: CXMT Corporation, Hefei (CN)

(72) Inventors: Guanjie LI, Hefei (CN); Nan WU, Hefei (CN)

(21) Appl. No.: 19/428,352

(22) Filed: Dec. 22, 2025

Related U.S. Application Data
(63) Continuation of application No. PCT/CN2025/130146, filed on Oct. 27, 2025.

(30) Foreign Application Priority Data
Mar. 24, 2025 (CN) 202510363124.4

(51) Int. Cl. H10B 12/00

(52) U.S. Cl. CPC H10B 12/30; H10B 12/03; H10B 12/05

(57) ABSTRACT

The semiconductor device includes an active layer, a word line structure, a conductive shield layer, a bit line structure, and a capacitor structure. A plurality of active layers are sequentially spaced apart along a first direction, and first spacer regions and second spacer regions are alternately disposed between adjacent active layers along the first direction. Each active layer includes a first doped region, a channel region, and a second doped region sequentially arranged along a second direction. The word line structure extends along a third direction and is disposed on a side of the channel region facing the first spacer region. The conductive shield layer extends along the third direction, is disposed in the second spacer region, and is spaced apart from the active layer. The bit line structure is electrically connected to the first doped region. The capacitor structure is electrically connected to the second doped region.

### CROSS REFERENCE TO RELATED APPLICATIONS

The present application claims priority to Chinese Patent Application No. 202510363124.4 filed with China National Intellectual Property Administration on Mar. 24, 2025 and entitled “SEMICONDUCTOR DEVICE AND MANUFACTURING METHOD THEREFOR”, the content of which is incorporated herein by reference in its entirety.

### BACKGROUND

A memory is a memory component for storing programs and various data information. A random access memory (random access memory, RAM) generally used in a computer system may be classified into a dynamic random access memory (dynamic random access memory, DRAM) and a static random-access memory (static random-access memory, SRAM), and the DRAM is a semiconductor memory device commonly used in a computer and is composed of a plurality of repetitive memory cells.

A memory cell generally includes a capacitor and a transistor, where a drain of the transistor is connected to a bit line, a source of the transistor is connected to the capacitor, and a word line of the memory cell can control a channel region of the transistor to be turned on or off, such that data information stored in the capacitor can be read through the bit line or the data information can be written into the capacitor through the bit line for storage.

At present, the reliability of semiconductor structures needs to be improved.

### SUMMARY

Embodiments of the present disclosure relate to the technical field of semiconductors, in particular to a semiconductor device and a manufacturing method therefor.

Embodiments of the present disclosure provide a semiconductor device and a manufacturing method therefor, which are at least beneficial for improving the reliability of the semiconductor device.

According to some embodiments of the present disclosure, in one aspect, the embodiments of the present disclosure provide a semiconductor device. The semiconductor device includes: a plurality of active layers sequentially spaced apart along a first direction, where first spacer regions and second spacer regions are alternately disposed between adjacent active layers along the first direction such that, along the first direction, two opposite sides of a same active layer are respectively adjacent to one of the first spacer regions and one of the second spacer regions, and each of the plurality of active layers includes a first doped region, a channel region, and a second doped region sequentially arranged along a second direction; a word line structure, where the word line structure is disposed on a side of the channel region facing the first spacer region, and extends along a third direction; a conductive shield part, where the conductive shield layer is positioned in the second spacer region and spaced apart from the active layer, the conductive shield layer extends along the third direction, and an orthographic projection of the conductive shield layer on a reference plane at least partially overlaps with an orthographic projection of the word line structure on the reference plane, the reference plane being a plane perpendicular to the first direction; a bit line structure, where the bit line structure extends along the first direction and is electrically connected to the first doped region; and a capacitor structure, where the capacitor structure extends along the second direction and is electrically connected to the second doped region.

According to some embodiments of the present disclosure, in another aspect, the embodiments of the present disclosure further provide a method for manufacturing a semiconductor device. The method includes: providing a base substrate, where a plurality of semiconductor layers are formed on the base substrate and are sequentially spaced apart from each other along a first direction; first spacer regions and second spacer regions are alternately disposed between adjacent semiconductor layers along the first direction such that, along the first direction, two opposite sides of a same semiconductor layer are respectively adjacent to one of the first spacer regions and one of the second spacer regions; capacitor holes and bit line holes, which are spaced apart along a second direction and extend along the first direction, are formed in the plurality of semiconductor layers, and each of the plurality of semiconductor layers disposed between the capacitor holes and the bit line holes includes a first doped region, a channel region, and a second doped region sequentially arranged along the second direction; forming a conductive shield part, where the conductive shield layer is positioned in the second spacer region and is spaced apart from the channel region, and an orthographic projection of the conductive shield layer (103) on a reference plane at least partially overlaps with an orthographic projection of the channel region (III) on the reference plane, the reference plane being a plane perpendicular to the first direction (X) ; etching the semiconductor layer to form active layers separated from each other, where each of the active layers includes the first doped region, the channel region, and the second doped region sequentially arranged along the second direction; forming a word line structure, where the word line structure is disposed on a surface of the channel region facing the first spacer region, and extends along a third direction; forming a bit line structure in each of the bit line holes, where the bit line structure extends along the first direction and is electrically connected to the first doped region; and forming a capacitor structure in each of the capacitor holes, where the capacitor structure extends along the second direction and is electrically connected to the second doped region.

In another aspect, the embodiments of the present disclosure further provide an electronic apparatus. The electronic apparatus includes: a processor; and a memory, where the memory is coupled to the processor, and at least one of the memory and the processor includes the semiconductor device according to any one of the embodiments of the present disclosure.

### BRIEF DESCRIPTION OF DRAWINGS

One or more embodiments are exemplarily illustrated with reference to figures in the corresponding drawings, and these exemplary illustrations are not to be construed as limiting the embodiments. Unless expressly stated otherwise, the figures in the drawings do not constitute a limitation of scale. To more clearly illustrate the technical solutions in the embodiments of the present disclosure or conventional technology, a brief introduction to the drawings required to be used in the embodiments is given hereinafter. It is evident that the drawings described hereinafter are merely some embodiments of the present disclosure. For those of ordinary skill in the art, other drawings may be further obtained based on these drawings without creative effort.

FIG. 1 is a schematic structural diagram of a semiconductor device according to an embodiment of the present disclosure;

FIG. 2 is a schematic cross-sectional diagram of FIG. 1 along the direction AA1;

FIGS. 3 to 9 are schematic structural diagrams corresponding to various steps in a method for manufacturing a semiconductor device according to an embodiment of the present disclosure; and

FIG. 10 is a schematic block diagram of a structure of an electronic apparatus according to some embodiments of the present disclosure.

Reference numerals in the figures are as follows:
X: first direction;
Y: second direction;
Z: third direction;
I: first doped region;
II: second doped region;
III: channel region;
100: base substrate;
101: active layer;
102: word line structure;
1021: gate dielectric layer;
1022: word line conductive layer;
103: conductive shield layer;
104: bit line structure;
105: capacitor structure;
115: lower electrode layer;
125: capacitor dielectric layer;
135: upper electrode layer;
145: conductive filling layer;
111: first spacer region;
113: first isolation layer;
121: second spacer region;
123: second isolation layer;
200: isolation layer;
201: semiconductor layer;
202: first portion;
203: second portion;
204: bit line hole;
205: capacitor hole.

### DESCRIPTION OF EMBODIMENTS

As is known from the background section, the reliability of semiconductor devices needs to be improved.

As the demand for high-performance and low-cost semiconductor devices increases, higher requirements are also put forward for the integration density of the semiconductor devices. In a 3D dynamic random access memory (3D dynamic random access memory, 3D DRAM) structure, memory cells (cell) are stacked to achieve more output per unit wafer area. Compared with a common planar DRAM structure, the 3D DRAM structure can effectively reduce the unit cost of the DRAM.

In a current 3D DRAM structure, a word line structure is usually disposed to surround a channel region of an active layer to form a gate-all-around structure, and the gate-all-around structure is beneficial for improving the control capability of the word line structure. However, the process of the gate-all-around structure is difficult, and due to the small distance between stacked active layers, the gate-all-around structure causes the word line structures corresponding to different active layers to be closer, resulting in a greater coupling effect between adjacent word line structures. If the thickness of the word line structure in the gate-all-around structure is reduced, it easily results in a relatively large resistance of the word line structure, which in turn leads to severe delay in the semiconductor device and affects the read/write performance of the device. If the word line structure is disposed only on one side of the active layer to form a single-gate structure, it is beneficial for increasing the size of the word line structure and reducing the process difficulty. However, there is still a problem of the passing gate effect (passing gate effect) between the word line structures of one active layer and another adjacent active layer, resulting in low reliability of the semiconductor device.

Embodiments of the present disclosure provide a semiconductor device and a manufacturing method therefor. In the semiconductor device, a plurality of active layers are vertically stacked along a first direction, a first spacer region or a second spacer region is provided between adjacent active layers, a word line structure is located on a surface, close to the first spacer, of a channel region of the active layer, and a conductive shield layer is disposed in the second spacer region between adjacent active layers, to isolate the word line structure corresponding to one active layer from that of an another adjacent active layer, thereby avoiding the passing gate effect between the word line structures of one active layer and another adjacent active layer. The word line structure is located on one side of the active layer along the first direction, which is beneficial for increasing the size of the word line structure and reducing the resistance of the word line structure, thereby reducing the delay of the semiconductor device and improving the read/write rate. In addition, the one-sided word line structure is beneficial for reducing the process difficulty.

The embodiments of the present disclosure will be described in detail below with reference to the drawings. However, those of ordinary skill in the art can understand that, in the embodiments of the present disclosure, numerous technical details are set forth to enable readers to better understand the present disclosure. However, the technical solutions claimed by the present disclosure can also be implemented even without these technical details and the various changes and modifications based on the following embodiments.

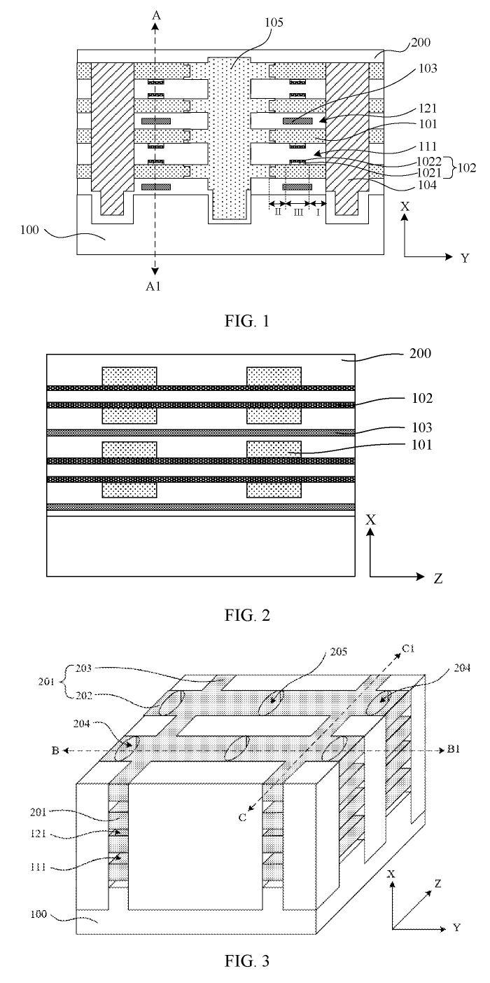

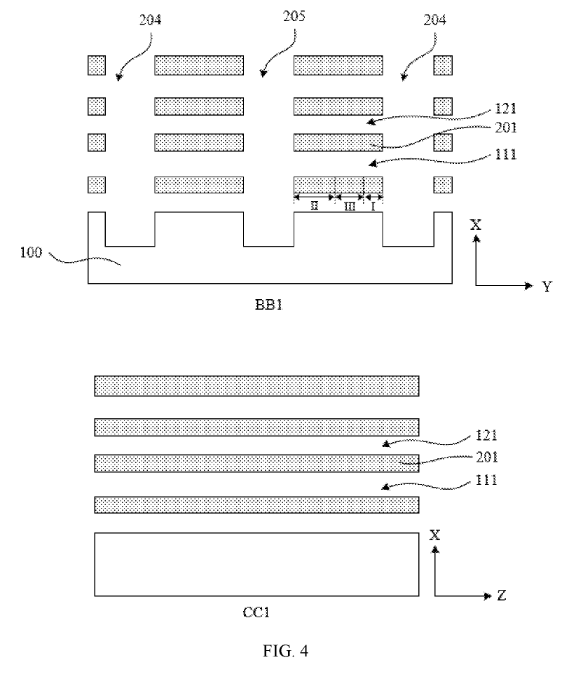

FIG. 1 is a schematic structural diagram of a semiconductor device according to an embodiment of the present disclosure; and FIG. 2 is a schematic cross-sectional diagram of FIG. 1 along the direction AA1.

Referring to FIGS. 1 and 2, the semiconductor device includes: an active layer 101, a word line structure 102, a conductive shield layer 103, a bit line structure 104, and a capacitor structure 105.

A plurality of active layers 101 are sequentially spaced apart along a first direction X, a first spacer region 111 or a second spacer region 121 is provided between adjacent active layers 101 along the first direction X, the first spacer region 111 and the second spacer region 121 are respectively located on two opposite sides of the same active layer 101 along the first direction X, and each active layer 101 includes a first doped region I, a channel region III, and a second doped region II sequentially arranged along a second direction Y.

The word line structure 102 is disposed on a side of the channel region III facing the first spacer region 111, and the word line structure 102 extends along a third direction Z.

The conductive shield layer 103 is located in the second spacer region 121 and spaced apart from the active layer 101. The conductive shield layer 103 extends along the third direction Z. The conductive shield part 103 at least partially directly faces the word line structure102 in the first direction X, that is, an orthographic projection of the conductive shield layer 103 on a reference plane at least partially overlaps with an orthographic projection of the word line structure 102 on the reference plane, the reference plane being a plane perpendicular to the first direction X.

The bit line structure 104 extends along the first direction X and is electrically connected to the first doped region I.

The capacitor structure 105 extends along the second direction Y and is electrically connected to the second doped region II.

In the semiconductor device provided by the embodiments of the present disclosure, a first spacer region 111 or a second spacer region 112 is provided between adjacent active layers 101 along the first direction X, a word line structure 102 is located on one side surface of a channel region III facing the first spacer region 111, conductive shield layer s 103 are spaced apart from each other on one side of the channel region III of the active layer 101 facing the second spacer region 121. In this way, in the first spacer region 111 between adjacent active layers 101, word line structures 102 corresponding to different active layers 101 can shield each other to avoid the passing gate effect between the word line structures 102 of one active layer 101 and another active layer 101; in the second spacer region 121 between adjacent active layers 101, the conductive shield layer 103 can play a shielding role to avoid the passing gate effect between the word line structures 102 of one active layer 101 and another active layer 101, thereby improving the reliability of the semiconductor device. The plurality of active layers 101 are spaced apart along the first direction X and the third direction Z, and a capacitor structure 105 is electrically connected to a second doped region II of each of the plurality of active layers 101 to form a memory cell. A plurality of memory cells arranged in a spatial array are beneficial for improving the space utilization. The word line structure 102 extends along the third direction Z, and a plurality of transistor structures arranged along the third direction Z share the same word line structure 102, to improve the control capability of the word line structure 102. A bit line structure 104 extends along the first direction X, and a plurality of transistors arranged along the first direction X share the same bit line structure 104, to improve the efficiency of the bit line structure 104.

In some embodiments, the conductive shield layer 103 may be short-circuited, i.e., grounded, to play a shielding role. In some other embodiments, the conductive shield layer 103 may also be applied with a voltage to play a back-gate role, thereby adjusting the threshold voltage of the transistor structure.

The material of the active layer 101 may include semiconductor materials such as silicon, gallium arsenide, silicon carbide, or gallium nitride. The material of the active layer 101 may further include at least one of indium gallium zinc oxide (indium gallium zinc oxide, IGZO), indium tungsten oxide (indium tungsten oxide, IWO), or indium tin oxide (indium tin oxide, ITO).

Referring to FIG. 1, in some embodiments, in the first direction X, a width of the second spacer region 121 is smaller than a width of the first spacer region 111. In this way, the conductive shield layer 103 can effectively suppress the occurrence of the passing gate effect between the word line structures 102 corresponding to one active layer 101 and another adjacent active layer 101, while providing more space for the word line structure 102, thereby reducing the resistance of the word line structure 102 and improving the transmission efficiency of the semiconductor device.

In some embodiments, the word line structure includes: a word line conductive layer 1022, where the word line conductive layer 1022 is disposed on a side of the channel region III facing the first spacer region 111, and the word line conductive layer 1022 extends along the second direction Y; and a gate dielectric layer 1021, where the gate dielectric layer 1021 is at least located between the channel region III and the word line conductive layer 1022. A thickness of the word line conductive layer 1022 is greater than or equal to a thickness of the conductive shield layer 103. In this way, in the first direction X, the conductive shield layer 103 occupies a small size, and the size of the word line conductive layer 1022 is increased as much as possible under the condition that the passing gate effect is suppressed, thereby reducing the resistance of the word line structure 102, improving the reliability of the transistor structure, and reducing the size of the semiconductor device.

In some embodiments, the gate dielectric layer 1021 is also located on the surface of the first doped region I facing the first spacer region 111. In the process of forming the gate dielectric layer 1021, the gate dielectric layer 1021 covers the surfaces of the first doped region I and the channel region III of the active layer 101. After the word line conductive layer 1022 is formed, only the word line conductive layer 1022 on the first doped region I may be removed, while the gate dielectric layer 1021 on the first doped region I is retained, thereby omitting one process step and improving the manufacturing efficiency of the semiconductor device.

The material of the word line conductive layer 1022 includes at least one of polycrystalline silicon, titanium nitride, titanium aluminide, tantalum nitride, nickel silicide, cobalt silicide, tantalum, aluminum, lanthanum, titanium, or tungsten.

The material of the gate dielectric layer 1021 includes silicon oxide, silicon nitride, metal oxide, metal oxynitride, metal silicide, a high-K material, a ferroelectric material, an anti-ferroelectric material, or a combination thereof. For example, the gate dielectric layer 1021 may include SiO2, Si3N4, HfO2, Al2O3, ZrO2, AlON, HfON, HfSiO, HfSiON, or the like.

The material of the conductive shield layer 103 includes at least one of TiN, TaN, Cu, Al, or W.

The material of the conductive shield layer 103 may be the same as the material of the word line conductive layer. In this way, the conductive shield layer 103 can be formed by using the process of forming the word line conductive layer, thereby improving the manufacturing efficiency of the semiconductor device. In other embodiments, the material of the conductive shield layer 103 may be different from the material of the word line conductive layer.

In some embodiments, the resistivity of the material of the conductive shield layer 103 is greater than or equal to the resistivity of the material of the word line conductive layer. In this way, the conductive shield layer 103 can achieve a sufficient shielding effect, and the material cost of the conductive shield layer 103 can be reduced.

In some embodiments, an orthographic projection of the word line structure 102 on a reference plane may be within an orthographic projection of the conductive shield layer 103 on the reference plane, where the reference plane is a plane perpendicular to the first direction X. In this way, it is beneficial for ensuring that the conductive shield layer 103 has a sufficient shielding effect on the word line structure 102.

As shown in FIG. 1, in some embodiments, a size of the conductive shield layer 103 in the second direction Y is greater than a size of the word line conductive layer 1022 in the second direction Y.

In the first direction X, the thickness of the conductive shield layer 103 may be 5 nm to 15 nm, for example, may be specifically 5 nm, 8 nm, 10 nm, 11 nm, 13 nm, 14 nm, or 15 nm. The size of the conductive shield layer 103 is within this range, which is beneficial for the conductive shield layer 103 to occupy as little space as possible while having a sufficient shielding effect, thereby improving the integration density of the semiconductor device.

In some embodiments, in the first direction X, the spacing between the conductive shield layer 103 and an adjacent active layer 101 is the same, which can facilitate the adjustment and control of the process parameters. In the actual process steps of manufacturing the semiconductor device, there may be process errors, and thus the spacing between the conductive shield layer 103 and the adjacent active layer 101 may be different.

The semiconductor device may further include: a base substrate 100; the plurality of active layers 101 are vertically stacked on the base substrate 100, and a bottom-layer active layer 101 is spaced apart from the base substrate 100. The bottom-layer active layer 101 is an active layer 101 closest to the base substrate 100 along the first direction X, and the bit line structure 104 and the capacitor structure 105 further extend into the base substrate 100. The conductive shield layer 103 is also located between the bottom-layer active layer 101 and the base substrate 100. The bit line structure 104 and the capacitor structure 105 further extend into the base substrate 100, which is beneficial for reducing the precision of the process size and improving the fault tolerance of the process size. The conductive shield layer 103 is also located between the bottom-layer active layer 101 and the base substrate 100, such that the conductive shield layer 103 can shield the active layer 101 from the base substrate 100, or when a voltage is applied to the conductive shield layer 103, the conductive shield layer can play a back-gate role for the bottom-layer active layer 101, thereby adjusting the threshold voltage of the bottom-layer transistor structure.

The base substrate 100 may be a semiconductor substrate, where the semiconductor substrate includes a silicon substrate, a silicon germanium substrate, a gallium arsenide substrate, a silicon carbide substrate, a gallium nitride substrate, or the like.

The material of the bit line structure 104 may be a single metal, a metal compound, or an alloy. The single metal may be cobalt, nickel, molybdenum, titanium, tungsten, tantalum, platinum, or the like; the metal compound may be tungsten nitride, tantalum nitride, or titanium nitride; and the alloy may be an alloy material composed of at least two of cobalt, nickel, molybdenum, titanium, tungsten, tantalum, or platinum.

It should be noted that, in FIGS. 1 and 2, other structures in the semiconductor device are hidden for the convenience of illustration. In some embodiments, the semiconductor device may further include: an isolation layer 200. The isolation layer 200 is filled in the first spacer region 111 and the second spacer region 121; the second doped region II is recessed relative to the isolation layer 200 disposed on two opposite sides of the second doped region II along the first direction X, and the isolation layer 200 exposes an end part of the second doped region II. The second doped region II is recessed relative to the isolation layer 200 disposed on two opposite sides of the second doped region II along the first direction X, such that a lower electrode layer is provided with a larger area, which is beneficial for improving the charge storage capacity of the capacitor structure 105.

The material of the isolation layer 200 includes silicon oxide, silicon nitride, silicon oxynitride, or the like.

The capacitor structure may include: a lower electrode layer, the lower electrode layer covering a surface of the end part of the second doped region exposed by the isolation layer, and further covering a surface of the isolation layer facing the active layer, where lower electrode layers corresponding to adjacent second doped regions along the first direction are electrically isolated from each other; a capacitor dielectric layer, where the capacitor dielectric layer is located on a surface of the lower electrode layer and is also located on a side surface of the isolation layer, and the capacitor dielectric layer encloses a hollow ring extending along the first direction to form a groove; an upper electrode layer, where the upper electrode layer is located on a surface of the capacitor dielectric layer; and a conductive filling layer, where the conductive filling layer is located on a surface of the upper electrode layer and fills up the groove. Lower electrode layers in the capacitor structures corresponding to different active layers are electrically isolated from each other, while the upper electrode layers are commonly shared, such that the space utilization and the charge storage capability of the capacitor structure can be improved.

In some embodiments, the lower electrode layer may be disposed around the end part of the second doped region, such that the contact area between the lower electrode layer and the second doped region is increased, and the transmission efficiency between the lower electrode layer and the second doped region is improved.

The material of the lower electrode layer includes at least one of platinum nickel, titanium, tantalum, cobalt, polycrystalline silicon, copper, tungsten, tantalum nitride, titanium nitride, or ruthenium.

The material of the capacitor dielectric layer includes silicon oxide, tantalum oxide, hafnium oxide, zirconium oxide, niobium oxide, titanium oxide, barium oxide, strontium oxide, yttrium oxide, lanthanum oxide, praseodymium oxide, barium strontium titanate, or other high-k materials.

The material of the upper electrode layer includes at least one of platinum nickel, titanium, tantalum, cobalt, polycrystalline silicon, copper, tungsten, tantalum nitride, titanium nitride, or ruthenium.

The material of the conductive filling layer includes copper, silver, gold, tungsten, tin, or lead.

In some embodiments, the lower electrode layer may have a U-shaped structure, and the upper electrode layer is located inside the U-shaped structure of the lower electrode layer. In other embodiments, the upper electrode layer may have a U-shaped structure, and the lower electrode layer is located inside the U-shaped structure of the upper electrode layer.

In some embodiments, the semiconductor device includes active layers 101 spaced apart along the second direction Y, and in the second direction Y, second doped regions II of adjacent active layers 101 directly face each other, and capacitor structures 105 corresponding to the directly faced second doped regions II share the upper electrode layer, such that the space utilization of the semiconductor device along the second direction Y and the charge storage capability of the capacitor structures 105 can be further improved.

In FIG. 1, two groups of active layers 101 arranged along the second direction Y are taken as an example. In other embodiments, multiple groups of active layers may be arranged along the second direction, and two adjacent groups of active layers share the upper electrode layer of the capacitor structure or share the bit line.

In the semiconductor device provided by the embodiments of the present disclosure, a first spacer region 111 or a second spacer region 112 is provided between adjacent active layers 101 along the first direction X, a word line structure 102 is located on one side surface of a channel region III facing the first spacer region 111, conductive shield layer s 103 are spaced apart from each other on one side of the channel region III of the active layer 101 facing the second spacer region 121. In this way, in the first spacer region 111 between adjacent active layers 101, word line structures 102 corresponding to different active layers 101 can shield each other to avoid the passing gate effect between the word line structures 102 of one active layer 101 and another active layer 101; in the second spacer region 121 between adjacent active layers 101, the conductive shield layer 103 can play a shielding role to avoid the passing gate effect between the word line structures 102 of one active layer 101 and another active layer 101, thereby improving the reliability of the semiconductor device. The plurality of active layers 101 are spaced apart along the first direction X and the third direction Z, and a capacitor structure 105 is electrically connected to a second doped region II of each of the plurality of active layers 101 to form a memory cell. A plurality of memory cells arranged in a spatial array are beneficial for improving the space utilization. The word line structure 102 extends along the third direction Z, and a plurality of transistor structures arranged along the third direction Z share the same word line structure 102, to improve the control capability of the word line structure 102. A bit line structure 104 extends along the first direction X, and a plurality of transistors arranged along the first direction X share the same bit line structure 104, to improve the efficiency of the bit line structure 104.

Another embodiment of the present disclosure provides a method for manufacturing a semiconductor device, which can be used to form the above semiconductor device to improve the performance of the semiconductor device. It should be noted that, for parts that are the same as or corresponding to those in the above embodiments, reference may be made to the corresponding descriptions of the above embodiments, and details are not described below again.

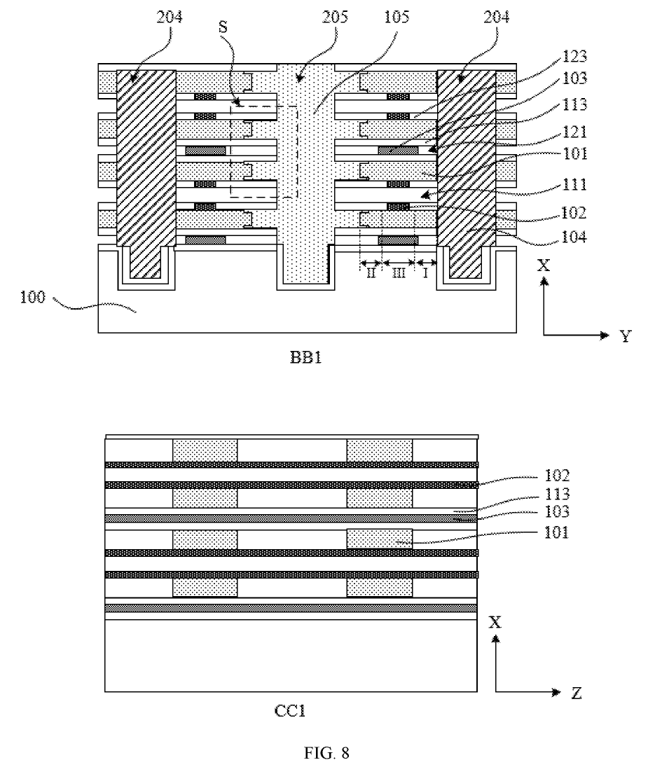

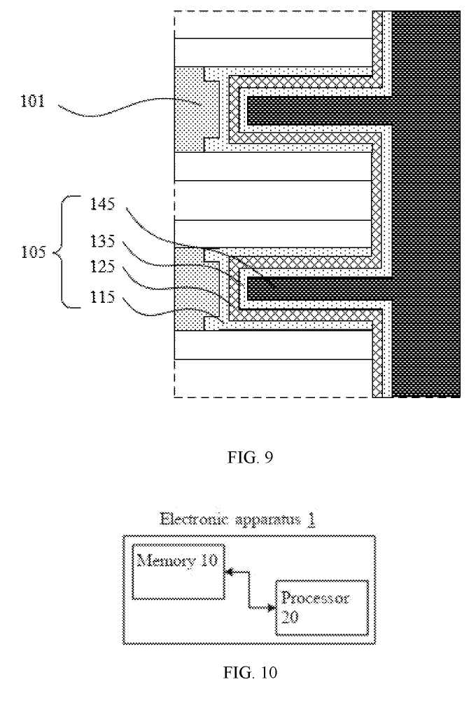

FIGS. 3 to 9 are schematic structural diagrams corresponding to various steps in a method for manufacturing a semiconductor device according to an embodiment of the present disclosure. The method for manufacturing a semiconductor device according to the embodiment is described in detail below with reference to the drawings. FIGS. 4 to 8 are schematic diagrams of FIG. 3 along the direction BB1 and the direction CC1. FIG. 9 is a schematic diagram of an enlarged partial structure corresponding to the dashed box S in FIG. 8.

Referring to FIGS. 3 to 9, the method for manufacturing a semiconductor device includes the following steps.

Referring to FIGS. 3 and 4, a base substrate 100 is provided. A plurality of semiconductor layers 201 are formed on the base substrate 100 and are sequentially spaced apart from each other along a first direction X. A first spacer region 111 or a second spacer region 121 is provided between adjacent semiconductor layers 201, and the first spacer region 111 and the second spacer region 121 are located on two opposite sides of the same semiconductor layer 201 along the first direction X. Moreover, capacitor holes 205 and bit line holes 204, which are spaced apart along a second direction Y and extend along the first direction X, are formed in the semiconductor layers 201, and the semiconductor layer 201 located between the capacitor holes 205 and the plurality of bit line holes 204 includes a first doped region I, a channel region III, and a second doped region II sequentially arranged along the second direction Y.

Specifically, the steps of providing the base substrate 100 and forming the semiconductor layers 201 include: forming alternately stacked initial sacrificial layers and initial semiconductor layers on the base substrate 100, where thicknesses of initial sacrificial layers on two side surfaces of the same initial semiconductor layer are different; patterning the initial sacrificial layers and the initial semiconductor layers in a thickness direction of the base substrate 100 to form the plurality of semiconductor layers 201 including first portions 202 extending along the second direction Y and second portions 203 extending along a third direction Z, where a width of each first portion 202 along the third direction Z is greater than a width of each second portion 203 along the second direction Y, and an insulating material is filled in a patterned region; patterning the semiconductor layers 201 and the initial sacrificial layers along the thickness direction of the base substrate 100 to form capacitor holes 205 and bit line holes 204, where each capacitor hole 205 is located in the first portion 202 of the semiconductor layer 201 and between two second portions 203, and each bit line hole 204 is located in the first portion 202 of the semiconductor layer 201 and on one side of the second portion 203 away from the capacitor hole 205; and removing the initial sacrificial layers based on the capacitor holes 205 and the bit line holes 204.

The material of the initial sacrificial layer includes one of silicon, germanium, silicon germanium, silicon carbide, or gallium arsenide. The insulating material includes silicon oxide, silicon nitride, or silicon oxynitride.

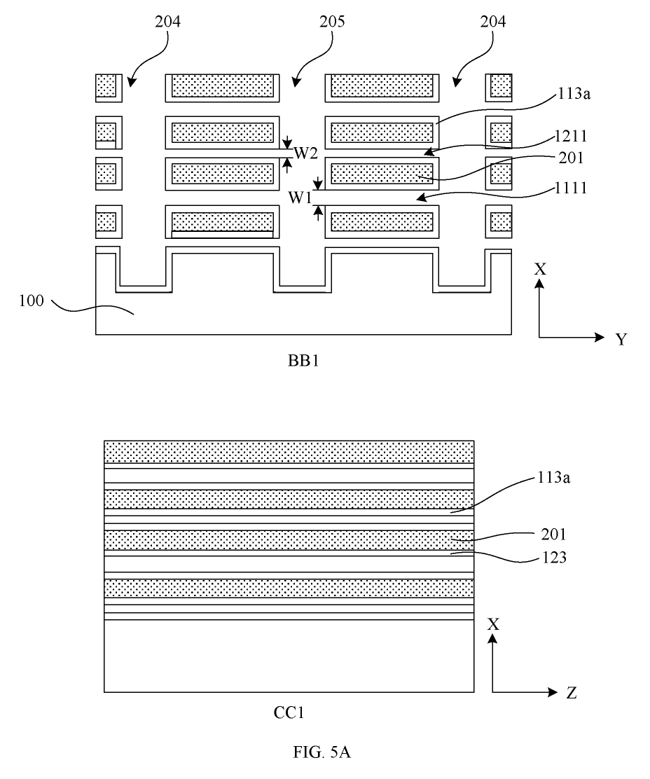

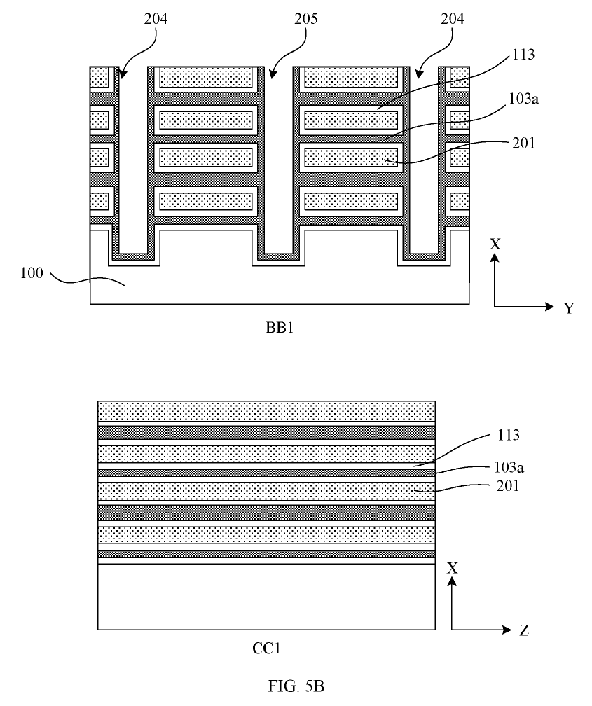

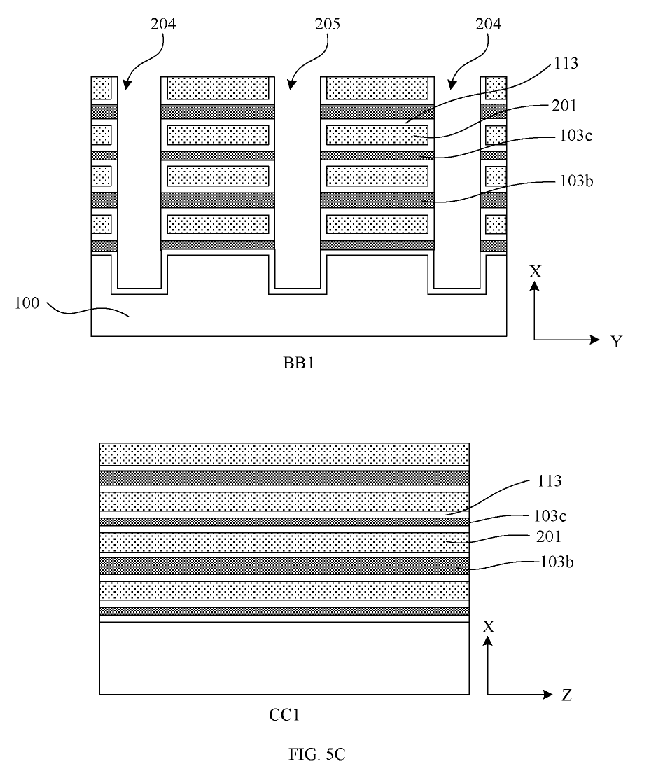

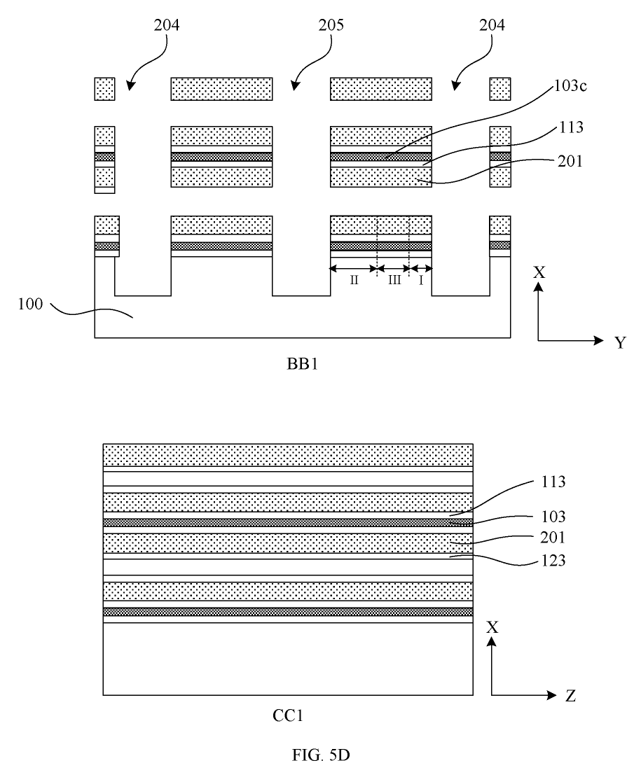

Referring to FIGS. 5A to 5F, a conductive shield layer 103 is formed. The conductive shield layer 103 is located in the second spacer region 121 and is spaced apart from the channel region III. The conductive shield layer 103 at least partially directly faces channel region III, that is, an orthographic projection of the conductive shield layer 103 on a reference plane at least partially overlaps with an orthographic projection of the channel region III on the reference plane, the reference plane being a plane perpendicular to the first direction X.

Based on the above process steps, the thicknesses of the initial sacrificial layers on both sides of the semiconductor layer 201 along the first direction X are different, and in the first direction X, the width of the second spacer region 121 is smaller than the width of the first spacer region 111. A process step of forming the conductive shield layer 103 includes: forming a first isolation layer 113, where the first isolation layer 113 is located on surfaces of the semiconductor layer 201 facing the first spacer region 111 and the second spacer region 121; after the first isolation layer 113 is formed, a first gap 1111 is formed between first isolation layers 113 directly facing each other in the first spacer region 111, and a second gap 1211 is formed between first isolation layers 113 directly facing each other in the second spacer region 121; in the first direction X, a width W1 of the first gap is greater than a width W2 of the second gap; forming initial conductive layers 103b and 103c that fill up the first gap 1111 and the second gap 1211; etching and removing the initial conductive layer 103b located in the first gap 1111 by using a wet process; and performing lateral etching on the initial conductive layer 103c located in the second gap 1211 to etch and remove portions of the initial conductive layer adjacent to the capacitor hole 205 and the bit line hole 204, with the remaining portion of the initial conductive layer configured to form the conductive shield layer 103.

Since the width W1 of the first gap is greater than the width W2 of the second gap, the first gap 1111 is more conducive to the entry of an etching solution. In the process of etching and removing the initial conductive layer 103c located in the first gap 1111 by using a wet process, the etching rate of the initial conductive layer 103b in the first gap 1111 is higher than the etching rate of the initial conductive layer 103c in the second gap 1211. By controlling the wet etching duration, the initial conductive layer 103b in the first gap 1111 can be removed faster, and the initial conductive layer 103c in the second gap 1211 is retained. Further, in the process of performing lateral etching on the initial conductive layer 103c located in the second gap 1211, the duration of keeping the etching solution in the capacitor hole 205 or the bit line hole 204 can be separately controlled, such that the remaining portion of the initial conductive layer 103c in the second gap 1211 serves as the conductive shield layer, and the position of the conductive shield layer 103 is directly opposite to the position of the channel region III.

Referring to FIGS. 5B to 5D, the specific step of forming the initial conductive layers 103b and 103c that fill up the first gap 1111 and the second gap 1211 includes: forming a conductive metal layer 103a, where the conductive metal layer 103a fills up the first gap 1111, the second gap 1211, the bit line hole 204, and the capacitor hole 205; and removing the portions of the conductive metal layer 103a located in the bit line hole 204 and the capacitor hole 205, and removing the portions of the conductive metal layer 103a located on side walls of the first isolation layer 113 facing the bit line hole 204 and the capacitor hole 204, with the remaining portions of the conductive metal layer serving as the initial conductive layers 103b and 103c. Since the widths of the first gap 1111 and the second gap 1211 are different, in order to fill up the second gap 1211 with the initial conductive layer 103c, the first gap 1111, the second gap 1211, the bit line hole 204, and the capacitor hole 2005 may be filled up first, and then conductive metal layers 103a in the capacitor hole 205, the bit line hole 204, and the first gap 1111 are gradually removed, such that the initial conductive layer 103c in the second gap 1211 is retained.

Referring to FIGS. 5E to 5F, the specific step of performing lateral etching on the initial conductive layer 103c located in the second gap 1211 includes: performing first lateral etching on side walls of the initial conductive layer 103c facing the bit line hole 204 and the capacitor hole 205; and performing, after the first lateral etching is performed, second lateral etching on the side wall of the initial conductive layer 103c facing the capacitor hole, with the remaining portion of the initial conductive layer serving as the conductive shield layer. That is, the initial conductive layer in the second gap is first etched by the first lateral etching by the same length, and then the portion of initial conductive layer at one side close to the capacitor hole is etched by the second lateral etching based on the capacitor hole, such that the remaining portion of the initial conductive layer corresponds to the channel region of the active layer.

With continued reference to FIG. 5F, after the conductive shield layer 103 is formed, the method includes: forming a second isolation layer 123. The second isolation layer 123 is located on the surface of the semiconductor layer 201 facing the first spacer region 111. The specific step includes: filling an insulating material in the capacitor hole 205, the bit line hole 204, positions in the first gap excluding the conductive shield layer 103, and the second gap; removing the insulating material in the capacitor hole 205 and the bit line hole 204, then removing the insulating material in the first gap, and finally removing the first isolation layer on the surface of the semiconductor layer 201 facing the first spacer region 111; and forming the second isolation layer 123, where the second isolation layer 123 covers the surface of the semiconductor layer 201 facing the first spacer region 111. Since the width of the first gap is greater than the width of the second gap, in the process of removing the insulating material in the first gap, it is difficult for the etching solution to enter the second gap. By controlling the etching duration, the insulating material and the first isolation layer in the first spacer region can be removed, and the insulating material and the first isolation layer in the second spacer region are largely retained.

In other embodiments, the sacrificial layers on two side surfaces of the semiconductor layer along the first direction may be made of different materials, such that the first spacer region and the second spacer region are formed step by step through selective etching, and the second isolation layer is formed in the first spacer region and the first isolation layer and the conductive shield layer are formed in the second spacer region.

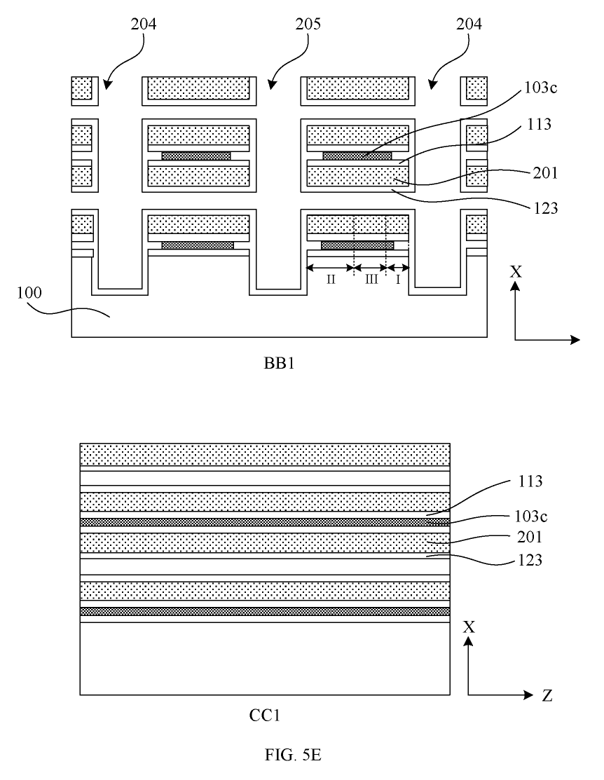

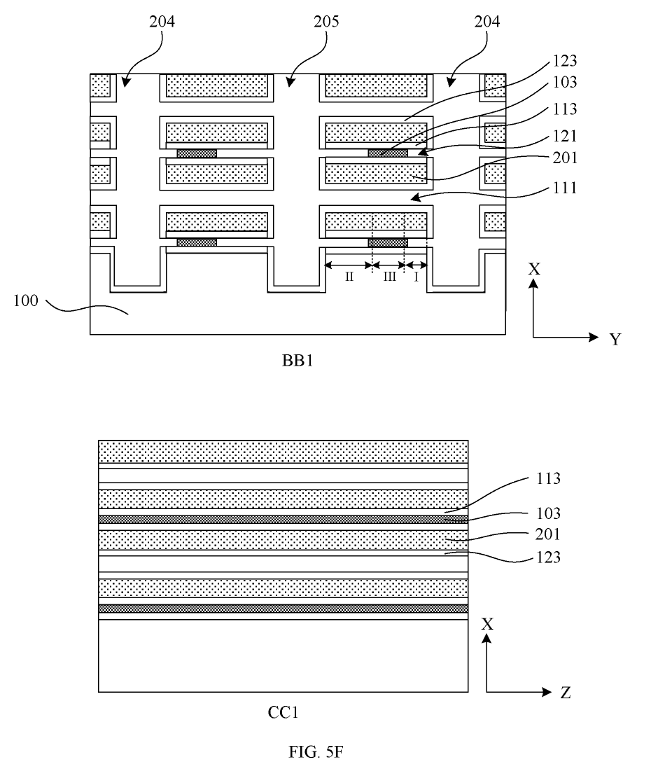

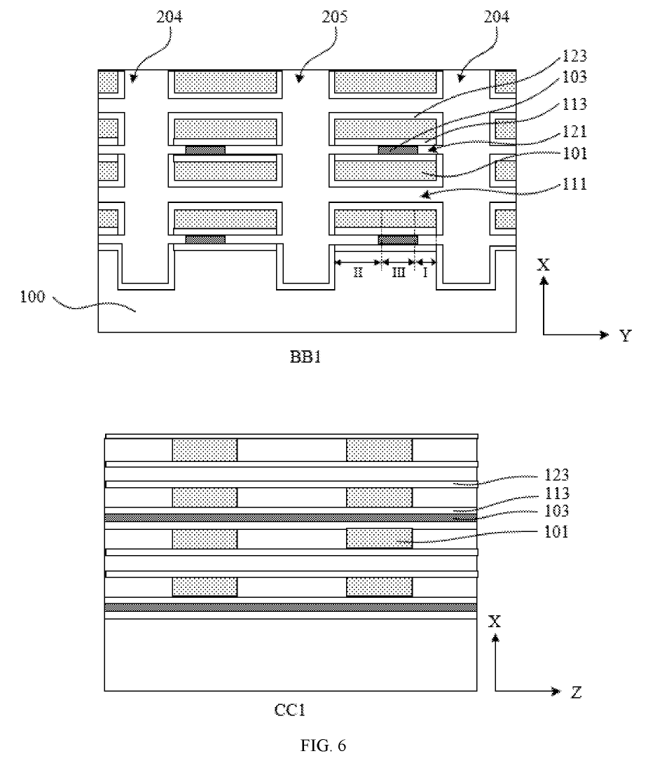

Referring to FIG. 6, the semiconductor layer 201 is etched to form active layers 101 separated from each other. Each active layer 101 includes a first doped region I, a channel region III, and a second doped region II sequentially arranged along the second direction Y.

Specifically, the step of etching the semiconductor layer 201 includes: removing the insulating material along the thickness direction of the base substrate 100 to expose a side wall of the semiconductor layer 201; performing lateral etching on the side wall of the semiconductor layer 201, with the remaining portion of the semiconductor layer 201 being the active layer 101; and then refilling the insulating material. Referring to FIGS. 3 and 6, since the width of the first portion 202 of the semiconductor layer 201 along the third direction Z is greater than the width of the second portion 203 along the second direction Y, in the process of performing lateral etching on the side wall of the semiconductor layer 201, the second portion 203 between first portions 202 is etched out more quickly, the first portion 202 is narrowed after being etched, and the remaining portion of the first portion 202 serves as the active layer 101.

In other embodiments, the width of the first portion of the semiconductor layer along the third direction may also be smaller than or equal to the width of the second portion along the second direction. In the process of patterning the insulating material along the thickness direction of the base substrate, only two side walls of the second portion along the second direction between the first portions may be exposed, and after the second portion between the first portions is etched, the semiconductor layer is spaced apart along the third direction, such that the remaining portion of the first portion serves as the active layer.

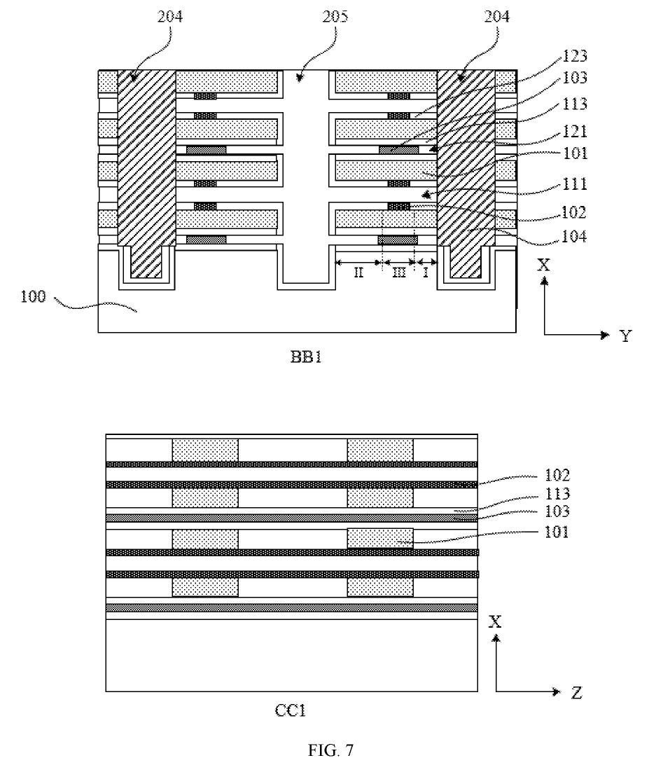

Referring to FIG. 7, a word line structure 102 is formed; the word line structure 102 is located on a surface of the channel region III facing the first spacer region 111, and the word line structure 102 extends along the third direction Z. A bit line structure 104 is formed in the bit line hole 204; the bit line structure 104 extends along the first direction X and is electrically connected to the first doped region I.

Specifically, the steps of forming the word line structure 102 and the bit line structure 104 include: removing the insulating material in the bit line hole 204; removing the second isolation layer 123 based on the bit line hole 204 to expose surfaces of the first doped region I and the channel region III facing the first spacer region 111; forming an initial word line structure, where the initial word line structure covers the surfaces of the first doped region I and the channel region III facing the first spacer region 111; etching back the initial word line structure to remove the initial word line structure on the surface of the first doped region I facing the first spacer region 111, where the initial word line structure on the surface of the channel region III facing the first spacer region 111 serves as the word line structure 102; filling the insulating material on the surface of the first doped region I facing the first spacer region 111; etching the insulating material on a side wall of the bit line hole 204 to expose a surface of the active layer 101 facing the bit line hole 204; and forming the bit line structure 104 in the bit line hole 204.

In the steps of forming the word line structure 102 and the bit line structure 104, the capacitor hole 205 is filled with an insulating material to occupy the position of the subsequently formed capacitor structure.

In some embodiments, after removing the second isolation layer 123 based on the bit line hole 204 to expose the surfaces of the first doped region I and the channel region III facing the first spacer region 111, the method further includes: removing the insulating material of partial thickness in the first spacer region 111, such that the subsequently formed word line structure 102 has a larger size, which is beneficial for reducing the resistance of the word line structure 102 and improving the transmission efficiency of the semiconductor device.

Referring to FIG. 8, a capacitor structure 105 is formed in the capacitor hole 205. The capacitor structure 105 extends along the second direction Y and is electrically connected to the second doped region II.

Specifically, referring to FIGS. 8 and 9, the specific step of forming the capacitor structure 105 includes: removing the insulating material in the capacitor hole 205 to expose a surface of the second doped region II of the active layer 101 facing the capacitor hole 205; performing lateral etching on the second doped region II to recess the second doped region II relative to the insulating material, the first isolation layer 113, and the second isolation layer 123 in the first spacer region 111 and the second spacer region 121 on two opposite sides of the second doped region II along the first direction X; forming an initial lower electrode layer, where the initial lower electrode layer covers an inner wall of the capacitor hole 205 and a surface of the second doped region II of the active layer 101; removing a portion of the initial lower electrode layer on the inner wall of the plurality of capacitor holes 205 along the first direction X, with the remaining portion of the initial lower electrode layer serving as a lower electrode layer 115; forming a capacitor dielectric layer 125, where the capacitor dielectric layer 125 covers the inner wall of the capacitor hole 205 and a surface of the lower electrode layer 115; forming an upper electrode layer 135, where the upper electrode layer 135 covers a surface of the capacitor dielectric layer 125; and forming a conductive filling layer 145, where the conductive filling layer 145 covers a surface of the upper electrode layer 135 and fills up the capacitor hole 205.

Referring to FIGS. 8 and 9, during the lateral etching of the second doped region II, the surface of the second doped region II facing the capacitor hole 205 protrudes toward the direction of the capacitor hole 205, such that the contact area between the subsequently formed lower electrode layer 115 and the second doped region II is increased, which is beneficial for improving the transmission efficiency between the active layer 101 and the capacitor structure 105.

Referring back to FIG. 1 and with continued reference to FIG. 9, in some embodiments, the lower electrode layer 115 of the capacitor structure 105 includes a first horizontal U-shaped part and a second horizontal U-shaped part with opposite opening orientations. The first horizontal U-shaped part encloses an end part of the second doped II region, a U-shaped bottom wall of the second horizontal U-shaped part is shared with a U-shaped bottom wall of the first horizontal U-shaped part, and the second horizontal U-shaped part extends on the first horizontal U-shaped part in an opposite direction. Both the first horizontal U-shaped part and the second U-shaped part extend in the second direction Y, an opening of the first horizontal U-shaped part faces the bit line hole 104, an opening of the second U-shaped part faces the capacitor hole 105, and an extension size of the first horizontal U-shaped part in the second direction Y is smaller than an extension size of the second horizontal U-shaped part in the second direction Y. In the first direction X, the first horizontal U-shaped part and the second U-shaped part have the same size.

With continued reference to FIGS. 1 and 9, in the first direction X, a top surface of the first U-shaped part does not extend beyond a top surface of the channel region III in the active layer 101. In the embodiments of the present disclosure, the second doped region II in the active layer 101 is recessed in the first direction X so that the second doped region II is narrowed. As a result, the first horizontal U-shaped part can enclose the end part of the second doped region II without extending beyond the overall height of the active layer 101, thereby avoiding adverse effects.

In some other embodiments, the step of forming the capacitor structure includes: removing the first isolation layer and the second isolation layer on both sides of the semiconductor layer in the first direction to expose the second doped region of the semiconductor layer; forming a lower electrode layer, where the lower electrode layer covers a surface of the second doped region and an inner wall of the capacitor hole, and removing the lower electrode on the inner wall of the capacitor hole, such that lower electrode layers on the second doped regions of different semiconductor layers are electrically isolated from each other; forming a capacitor dielectric layer, where the capacitor dielectric layer covers a surface of the lower electrode layer and the inner wall of the capacitor hole; forming an upper electrode layer, where the upper electrode layer covers a surface of the capacitor dielectric layer; and forming a conductive filling layer, where the conductive filling layer covers a surface of the upper electrode layer and fills up the capacitor hole.

The first isolation layer 113, the second isolation layer 123, and the insulating material filled between the active layer 101, the word line structure 102, the bit line structure 104, the capacitor structure 105, and the conductive shield layer 103 serve as the isolation layers in the above embodiments.

According to the method for manufacturing a semiconductor structure provided by the embodiments of the present disclosure, a plurality of active layers 101 are formed and spaced apart along the first direction X and the third direction Z, and the capacitor structure 105 is electrically connected to the second doped region II of each active layer 101 to form a memory cell. A plurality of memory cells arranged in a spatial array are beneficial for improving the space utilization. The formed word line structure 102 extends along the third direction Z, and a plurality of transistor structures arranged along the third direction Z share the same word line structure 102, to improve the control capability of the word line structure 102. The formed bit line structure 104 extends along the first direction X, and a plurality of transistors arranged along the first direction X share the same bit line structure 104, to improve the efficiency of the bit line structure 104. A first spacer region 111 or a second spacer region 121 is provided between adjacent active layers 101 along the first direction X, a word line structure 102 is located on one side surface of a channel region III facing the first spacer region 111, conductive shield layer s 103 are spaced apart from each other on one side of the channel region III of the active layer 101 facing the second spacer region 121. In this way, in the first spacer region 111 between adjacent active layers 101, word line structures 102 corresponding to different active layers 101 can shield each other to avoid the passing gate effect between the word line structures 102 of one active layer 101 and another active layer 101; in the second spacer region 121 between adjacent active layers 101, the conductive shield layer 103 can play a shielding role to avoid the passing gate effect between the word line structures 102 of one active layer 101 and another active layer 101, thereby improving the reliability of the semiconductor device.

Those of ordinary skill in the art can understand that the foregoing implementations are specific embodiments of practicing the present disclosure, while in practical application, various changes can be made to the implementations in form and detail without departing from the spirit and scope of the present disclosure.

What is claimed is:

1. A semiconductor device, comprising:
a plurality of active layers sequentially spaced apart along a first direction, wherein first spacer regions and second spacer regions are alternately disposed between adjacent active layers along the first direction such that, along the first direction, two opposite sides of a same active layer are respectively adjacent to one of the first spacer regions and one of the second spacer regions, and each of the plurality of active layers comprises a first doped region, a channel region, and a second doped region sequentially arranged along a second direction;
a word line structure, wherein the word line structure is disposed on a side of the channel region facing the first spacer region, and extends along a third direction;
a conductive shield layer, wherein the conductive shield layer is positioned in the second spacer region and spaced apart from the active layer, the conductive shield layer extends along the third direction, and an orthographic projection of the conductive shield layer on a reference plane at least partially overlaps with an orthographic projection of the word line structure on the reference plane, the reference plane being a plane perpendicular to the first direction;
a bit line structure, wherein the bit line structure extends along the first direction and is electrically connected to the first doped region; and
a capacitor structure, wherein the capacitor structure extends along the second direction and is electrically connected to the second doped region.

2. The semiconductor device according to claim 1, wherein in the first direction, a width of the second spacer region is smaller than a width of the first spacer region.

3. The semiconductor device according to claim 1, wherein the word line structure comprises:
a word line conductive layer, wherein the word line conductive layer is disposed on the side of the channel region facing the first spacer region, and extends along the second direction; and
a gate dielectric layer, wherein the gate dielectric layer is at least positioned between the channel region and the word line conductive layer;
wherein in the first direction, a thickness of the word line conductive layer is greater than or equal to a thickness of the conductive shield layer.

4. The semiconductor device according to claim 3, wherein the orthographic projection of the word line structure on the reference plane is within the orthographic projection of the conductive shield layer on the reference plane.

5. The semiconductor device according to claim 3, wherein a size of the conductive shield layer in the second direction is greater than a size of the word line conductive layer in the second direction.

6. The semiconductor device according to claim 3, wherein a material of the conductive shield layer is the same as a material of the word line conductive layer.

7. The semiconductor device according to claim 1, wherein the material of the conductive shield layer comprises at least one of TiN, TaN, Cu, Al, or W.

8. The semiconductor device according to claim 3, wherein resistivity of the material of the conductive shield layer is greater than or equal to resistivity of the material of the word line conductive layer.

9. The semiconductor device according to claim 1, wherein the thickness of the conductive shield layer is 5 nm to 15 nm.

10. The semiconductor device according to claim 1, wherein in the first direction, the conductive shield layer is disposed between two adjacent active layers and is equally spaced from the two adjacent active layers.

11. The semiconductor device according to claim 1, further comprising:
a base substrate, wherein the plurality of active layers are vertically stacked on the base substrate, and a bottom-layer active layer is spaced apart from the base substrate, wherein the bottom-layer active layer is an active layer closest to the base substrate along the first direction, and the bit line structure and the capacitor structure further extend into the base substrate; and
the conductive shield layer is further disposed between the bottom-layer active layer and the base substrate.

12. The semiconductor device according to claim 1, comprising the active layers spaced apart along the second direction, and in the second direction, the second doped regions of adjacent active layers directly face each other, and capacitor structures electrically connected to the second doped regions of the adjacent active layers that directly faced each other share upper electrode layers.

13. The semiconductor device according to claim 12, further comprising:
an isolation layer, wherein the isolation layer is filled in the first spacer region and the second spacer region, the second doped region is recessed relative to the isolation layer disposed on two opposite sides of the second doped region, and the isolation layer exposes an end part of the second doped region; and
the capacitor structure comprises:
a lower electrode layer covering a surface of the end part of the second doped region exposed by the isolation layer, and further covering a surface of the isolation layer facing the active layer, wherein the lower electrode layers corresponding to adjacent second doped regions along the first direction are electrically isolated from each other;
a capacitor dielectric layer disposed on a surface of the lower electrode layer and further disposed on a side surface of the isolation layer, wherein the capacitor dielectric layer encloses a hollow ring extending along the first direction to form a groove;
an upper electrode layer disposed on a surface of the capacitor dielectric layer; and
a conductive filling layer disposed on a surface of the upper electrode layer and filling the groove.

14. The semiconductor device according to claim 1, wherein the conductive shield layer is grounded.

15. The semiconductor device according to claim 1, wherein the conductive shield layer is connected to a voltage.

16. The semiconductor device according to claim 1, wherein a lower electrode layer of the capacitor structure comprises a first horizontal U-shaped part and a second horizontal U-shaped part with opposite opening orientations, wherein the first horizontal U-shaped part encloses an end part of the second doped region, a U-shaped bottom wall of the second horizontal U-shaped part is shared with a U-shaped bottom wall of the first horizontal U-shaped part, and the second horizontal U-shaped part extends on the first horizontal U-shaped part in an opposite direction.

17. A method for manufacturing a semiconductor device, comprising:
providing a base substrate, wherein a plurality of semiconductor layers are formed on the base substrate and are sequentially spaced apart from each other along a first direction; first spacer regions and second spacer regions are alternately disposed between adjacent semiconductor layers along the first direction such that, along the first direction, two opposite sides of a same semiconductor layers are respectively adjacent to one of the first spacer regions and one of the second spacer regions; capacitor holes and bit line holes, which are spaced apart along a second direction and extend along the first direction, are formed in the plurality of semiconductor layers, and each of the plurality of semiconductor layers disposed between the capacitor holes and the bit line holes comprises a first doped region, a channel region, and a second doped region sequentially arranged along the second direction;
forming a conductive shield part, wherein the conductive shield layer is positioned in the second spacer region and the conductive shield layer is spaced apart from the channel region, and an orthographic projection of the conductive shield layer on a reference plane at least partially overlaps with an orthographic projection of the channel region on the reference plane, the reference plane being a plane perpendicular to the first direction;
etching the semiconductor layer to form active layers separated from each other, wherein each of the active layers comprises the first doped region, the channel region, and the second doped region sequentially arranged along the second direction;
forming a word line structure, wherein the word line structure is disposed on a surface of the channel region facing the first spacer region, and extends along a third direction;
forming a bit line structure in each of the bit line holes, wherein the bit line structure extends along the first direction and is electrically connected to the first doped region; and
forming a capacitor structure in each of the capacitor holes, wherein the capacitor structure extends along the second direction and is electrically connected to the second doped region.

18. The method for manufacturing a semiconductor device according to claim 17, wherein in the first direction, a width of the second spacer region is smaller than a width of the first spacer region; and
a process step of forming the conductive shield layer comprises:
forming a first isolation layer, wherein the first isolation layer is disposed on surfaces of the semiconductor layer facing the first spacer region and the second spacer region; after the first isolation layer is formed, a first gap is formed between first isolation layers directly facing each other in the first spacer region, and a second gap is formed between first isolation layers directly facing each other in the second spacer region; in the first direction, a width of the first gap is greater than a width of the second gap;
forming initial conductive layers that fill up the first gap and the second gap;
etching and removing the initial conductive layer disposed in the first gap by using a wet process; and
performing lateral etching on the initial conductive layer disposed in the second gap to etch and remove portions of the initial conductive layer adjacent to the capacitor hole and the bit line hole, with a remaining portion of the initial conductive layer configured to form the conductive shield layer.

19. The method for manufacturing a semiconductor device according to claim 18, wherein forming the initial conductive layers that fill up the first gap and the second gap comprises:
forming a conductive metal layer, wherein the conductive metal layer fills up the first gap, the second gap, the bit line hole, and the capacitor hole; and
removing portions of the conductive metal layer disposed in the bit line hole and the capacitor hole, and removing portions of the conductive metal layer disposed on side walls of the first isolation layer facing the bit line hole and the capacitor hole, with remaining portions of the conductive metal layer serving as the initial conductive layers; and
performing the lateral etching on the initial conductive layer disposed in the second gap comprises:
performing first lateral etching on side walls of the initial conductive layer facing the bit line hole and the capacitor hole; and
performing, after the first lateral etching is performed, second lateral etching on the side wall of the initial conductive layer facing the capacitor hole, with a remaining portion of the initial conductive layer serving as the conductive shield layer.

20. An electronic apparatus, comprising:
a processor; and
a memory, wherein the memory is coupled to the processor, and at least one of the memory and the processor comprises the semiconductor device according to claim 1.
